(19) United States
(12) Patent Application Publication
(10) Pub. No.: US 2025/0274105 A1
(43) Pub. Date: Aug. 28, 2025

(54) ACOUSTIC WAVE FILTER AND RADIO FREQUENCY MODULE

(71) Applicant: MURATA MANUFACTURING CO., LTD., Kyoto (JP)

(72) Inventor: Shun HARADA, Kyoto (JP)

(21) Appl. No.: 18/940,076

(22) Filed: Nov. 7, 2024

(30) Foreign Application Priority Data
Feb. 26, 2024 (JP) 2024-026594

(51) Int. Cl. H03H 9/64; H03F 1/26

(52) U.S. Cl. CPC H03H 9/6483; H03F 1/26; H03F 2200/294

(57) ABSTRACT

An acoustic wave filter includes: a plurality of serial arm resonant devices including serial arm resonators disposed on a serial arm path connecting input/output terminals; one or more parallel arm resonant devices including a parallel arm resonator connected between the serial arm path and the ground; an inductor connected between the ground and a first path connecting the serial arm resonators. The serial arm resonator is connected closest to the input/output terminal among the plurality of serial arm resonant devices, the one or more parallel arm resonant devices, and the inductor, and the serial arm resonator has the highest resonant frequency among the plurality of serial arm resonant devices.

### CROSS REFERENCE TO RELATED APPLICATION

This application claims priority from Japanese Patent Application No. 2024-026594 filed on Feb. 26, 2024. The content of this application is incorporated herein by reference in its entirety.

### BACKGROUND ART

The present disclosure relates to an acoustic wave filter and a radio frequency module.

International Publication No. 2019/064990 (FIG. 13) discloses a radio frequency front end circuit including low-noise amplifiers that amplify radio frequency reception signals and bandpass filters connected to the input terminals of the respective low-noise amplifiers.

### BRIEF SUMMARY

Each low-noise amplifier has capacitive input impedance. To achieve impedance matching between the low-noise amplifier and a corresponding one of bandpass filter in the radio frequency front end circuit disclosed, for example, in International Publication No. 2019/064990, it is effective to connect an inductor between the ground and a path connecting the low-noise amplifier and the bandpass filter. However, connecting the inductor needs to dispose a DC blocking capacitor in series to the path to prevent leakage of DC bias current to be supplied to the low-noise amplifier.

However, if the DC blocking capacitor is disposed in series to the input terminal of the low-noise amplifier, impedance mismatching occurs in the frequency band for a radio frequency reception signal, leading to the occurrence of transmission loss. As the result, the noise figure of the low-noise amplifier is deteriorated on occasions.

Accordingly, the present disclosure provides an acoustic wave filter and a radio frequency module with which the DC blocking and the impedance matching in the pass band are ensured.

An acoustic wave filter according to an aspect of the present disclosure includes a plurality of serial arm resonant devices including a first serial arm resonant device and a second serial arm resonant device, the first serial arm resonant device being disposed on a serial arm path connecting a first input/output terminal and a second input/output terminal; one or more parallel arm resonant devices connected between the serial arm path and ground; and a first inductor connected between the ground and a first path connecting the first serial arm resonant device and the second serial arm resonant device. The first serial arm resonant device is connected closest to the first input/output terminal among the plurality of serial arm resonant devices, the one or more parallel arm resonant devices, and the first inductor, and the first serial arm resonant device has a highest resonant frequency among the plurality of serial arm resonant devices.

A radio frequency module according to an aspect of the present disclosure includes the acoustic wave filter and the low-noise amplifier having the input terminal connected to the first input/output terminal.

According to the present disclosure, the acoustic wave filter and the radio frequency module with which the DC blocking and the impedance matching in the pass band are ensured may be provided.

### BRIEF DESCRIPTION OF THE DRAWINGS

FIG. 1 is a view of the circuit configuration of an acoustic wave filter and a radio frequency module according to an embodiment;

FIGS. 2AA-2AC depict a plan view and a cross-sectional view schematically illustrating a first example of an acoustic wave resonator included in the acoustic wave filter according to the embodiment;

FIG. 2B is a cross-sectional view schematically illustrating a second example of the acoustic wave resonator included in the acoustic wave filter according to the embodiment;

FIG. 2C is a cross-sectional view schematically illustrating a third example of the acoustic wave resonator included in the acoustic wave filter according to the embodiment;

FIG. 3A is a view of the circuit configuration of an acoustic wave filter according to Comparative Example 1;

FIGS. 3BA and 3BB illustrate a Smith chart representing the bandpass characteristic and the impedance of the acoustic wave filter according to Comparative Example 1;

FIGS. 4A-4C illustrate a Smith chart representing the bandpass characteristic of the acoustic wave filter according to the embodiment, the capacitance characteristic of a first serial arm resonant device, and the impedance of the acoustic wave filter;

FIGS. 5A-5C illustrate a Smith chart representing the bandpass characteristic of an acoustic wave filter according to Comparative Example 2, the capacitance characteristic of a first serial arm resonant device, and the impedance of the acoustic wave filter;

FIGS. 6A-6C illustrate a Smith chart representing the bandpass characteristic of an acoustic wave filter according to Comparative Example 3, the capacitance characteristic of a first serial arm resonant device, and the impedance of the acoustic wave filter;

FIG. 7A is a view of the circuit configuration of the acoustic wave filter according to the embodiment;

FIG. 7B is a plan view of the terminal layout of the acoustic wave filter according to the embodiment;

FIG. 7C is a plan view of the terminal layout of an acoustic wave filter according to Modification 1 of the embodiment;

FIG. 8A is a view of the circuit configuration of a radio frequency module according to Modification 2 of the embodiment; and

FIG. 8B is a plan view of the component configuration of the radio frequency module according to Modification 2 of the embodiment.

### DETAILED DESCRIPTION

Hereinafter, an embodiment of the present disclosure will be described in detail by using the drawings. The embodiment to be described later represents a comprehensive or specific example. Accordingly, a numerical value, a shape, a material, a component, the arrangement of the component and the like described in the following embodiment is an example and are not intended to limit the present disclosure. Among components in the following embodiment, a component that is not described in an independent claim is described as an optional component. The sizes and the ratio of the sizes of components in the drawings are not necessarily precisely illustrated.

Each drawing is a schematic view appropriately subjected to emphasis, omission, or ratio control to describe the present disclosure, is not necessarily strictly illustrated, and has a shape, a positional relationship and a ratio different from actual ones on occasions. Substantially the same components are denoted by the same reference numerals throughout the drawings and redundancy is omitted or simplified in some cases.

In the circuit configuration of the present disclosure, the term “connected” includes not only “directly connected” by using a connection terminal and/or a wiring conductor but also “electrically connected” with a matching element or a switching circuit interposed between one component and the other component”. In addition, the phrase “connected between A and B” denotes that a component is connected between A and B and to both of A and B.

In the present disclosure, the term “terminal” denotes a point where a conductor in the element ends. If the impedance of the conductor between elements is sufficiently low, the terminal is interpreted as not only a single point but also as any point (a node) on the conductor between the elements or the entire conductor.

In the circuit element layout of the present disclosure, the phrase “a circuit element A is disposed in series to a path B” denotes that the signal input terminal and the signal output terminal of the circuit element A are connected to two respective wiring elements forming at least part of the path B. At least one of the two wiring elements may be an electrode or a terminal.

In the drawings described below, an x axis and a y axis are axes orthogonal to each other on a plane parallel to the main surface of a substrate. Specifically, if the substrate has a rectangular shape in plan view, the x axis is parallel to a first side of the substrate, and the y axis is parallel to a second side orthogonal to the first side of the substrate. A z axis is an axis perpendicular to the main surface of the substrate. The positive direction of the z axis denotes an upward direction, and the negative direction thereof denotes a downward direction.

Terms representing a relationship between elements such as “parallel” and “perpendicular”, a term representing the shape of an element such as “rectangular”, and a numerical value range indicate not only strict meaning but also inclusion of substantially the same range, for example, an error of approximately several percent.

In the component layout of the present disclosure, the phrase “in plan view of the main surface (of the substrate)” denotes seeing an object orthographically projected on the xy plane in the positive direction of the z axis. The phrase “A overlaps with B in plan view” denotes that at least part of the region of A orthographically projected on the xy plane overlaps with at least part of the region of B orthographically projected on the xy plane. The phrase “A is disposed between B and C” denotes that at least one of a plurality of lines connecting any point in B and any point in C passes through A.

In the component layout of the present disclosure, the phrase “a component is disposed on the substrate” includes disposition of the component on the main surface of the substrate and disposition of the component in the substrate. The phrase “a component is disposed on the main surface of a substrate” includes disposition of the component above the main surface without necessarily being in contact with the main surface (for example, the component is stacked on a different component disposed in contact with the main surface), in addition to disposition of the component in contact with the main surface of the substrate. The phrase “a component is disposed on the main surface of a substrate” may also include disposition of the component in a recessed portion formed in the main surface. The term “a component is disposed in the substrate” includes: encapsulation of the component in the module substrate; disposition of the entire component between main surfaces of the substrate but exposure of part of the component from the substrate; and disposition of only part of the component in the substrate.

In the embodiment below, the pass band of a filter is defined as a frequency band between two frequencies one of which has a value of 3 dB higher than the lowest value of insertion loss in the pass band.

The term “acoustic wave resonant device (a serial arm resonant device and a parallel arm resonant device) is defined as one of: (1) a resonance circuit including an acoustic wave resonator and a circuit connected in parallel to the acoustic wave resonator (or a circuit element) (a circuit in parallel connection between an acoustic wave resonator and a circuit (or a circuit element); (2) a resonance circuit (a circuit in serial connection between an acoustic wave resonator and a circuit (or a circuit element)) having a configuration that includes a circuit (or a circuit element) connected to an acoustic wave resonator and only one of two input/output terminals of the acoustic wave resonator and in which a different circuit (and a different circuit element) and the ground are not connected to a connection node connecting the acoustic wave resonator and the circuit (or the circuit element); (3) a resonance circuit (a circuit in parallel connection between divided resonators) including a plurality of acoustic wave resonators connected in parallel to each other; and (4) a resonance circuit (a circuit in series connection between divided resonators) that includes a plurality of acoustic wave resonators connected in series to each other and that has a configuration in which a circuit (and a circuit element) other than the plurality of acoustic wave resonators and the ground are not connected to a connection node connecting a plurality of acoustic wave resonators.

The resonant frequency and the anti-resonant frequency described in the above-mentioned embodiment and modifications are derived in the following manner. For example, in a state where the acoustic wave resonator or the acoustic wave resonant device is not connected to a different circuit element, a RF probe is brought into contact with two input/output electrodes of the acoustic wave resonator or the acoustic wave resonant device, and reflection characteristics (impedance characteristics) are measured with a network analyzer or the like.

The electrostatic capacitance of the acoustic wave resonator or the acoustic wave resonant device is derived in the following manner. In a state where the acoustic wave resonator or the acoustic wave resonant device is not connected to a different circuit element, a probe is brought into contact with two input/output electrodes of the acoustic wave resonator or the acoustic wave resonant device, and capacitance in DC is measured with a network analyzer, an impedance meter, or the like. The electrostatic capacitance may be compared between a plurality of surface acoustic wave resonators or between a plurality of surface acoustic wave resonant devices by actually measuring the number of pairs, the interdigital width, the pitch, and the duty of interdigital transducer (IDT) electrodes.

In the present disclosure, the term “band” denotes at least one of an uplink operating band and a downlink operating band in a frequency band defined in advance, for a communication system built up by using, for example, radio access technology (RAT), by a standardization organization or the like (such as 3GPP (registered trademark) or Institute of Electrical and Electronics Engineers (IEEE)). In this embodiment, for example, a long term evolution (LTE) system, a 5th Generation—New Radio (5G-NR) system, a wireless local area network (WLAN) system, and the like are usable as a communication system, but the communication system is not limited to these. The uplink operating band in the frequency band denotes a frequency range designated for an uplink in the frequency band. The downlink operating band in the frequency band denotes a frequency range designated for a downlink.

### EMBODIMENT

### 1 Circuit Configuration of Acoustic Wave Filter 1 and Radio Frequency Module 100

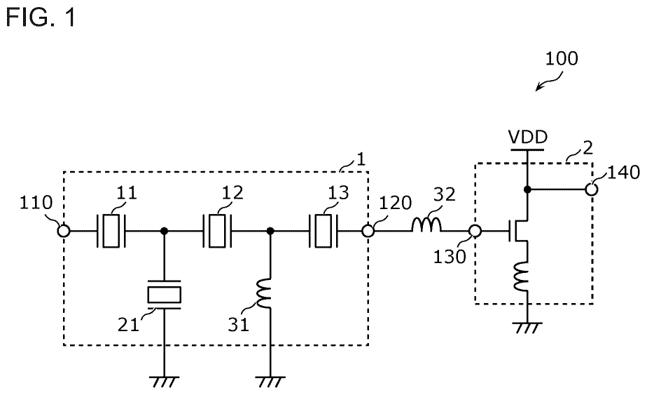

FIG. 1 is a view of the circuit configuration of an acoustic wave filter 1 and a radio frequency module 100 according to an embodiment. As illustrated in FIG. 1, the radio frequency module 100 includes the acoustic wave filter 1, a low-noise amplifier 2, and an inductor 32.

The low-noise amplifier 2 has an input terminal 130 and an output terminal 140, and the input terminal 130 is connected to an input/output terminal 120 of the acoustic wave filter 1 with the inductor 32 interposed therebetween. The low-noise amplifier 2 includes an amplifying transistor that is, for example, a field effect transistor (FET) or a bipolar transistor (Bipolar Transistor). The gate (or the base) of the amplifying transistor is connected to the input terminal 130 without necessarily a capacitive element interposed therebetween, the drain (or the collector) thereof is connected to the output terminal 140, and the source (or the emitter) thereof is connected to the ground. Further, a DC bias voltage (DC bias current) is supplied to the gate (or the base) of the amplifying transistor. With the configuration above, in response to the supply of the DC bias voltage (DC bias current) to the gate (or the base), the low-noise amplifier 2 thereby amplifies a radio frequency signal having passed through the acoustic wave filter 1 and outputs the radio frequency signal to the output terminal 140. The input impedance of the low-noise amplifier 2 is capacitive and high impedance.

The inductor 32 is an example of a second inductor and is disposed in series to a path connecting the input/output terminal 120 and the input terminal 130. The inductor 32 is a circuit element for performing impedance matching between the low-noise amplifier 2 having the capacitive input impedance and the acoustic wave filter 1. The inductor 32 does not have to be provided.

The acoustic wave filter 1 is a bandpass filter and includes serial arm resonators 11, 12, and 13, a parallel arm resonator 21, an inductor 31, an input/output terminal 110, and the input/output terminal 120.

Each of the serial arm resonators 11 to 13 is an example of the acoustic wave resonant device including an acoustic wave resonator and is disposed on a serial arm path connecting the input/output terminal 110 (a second input/output terminal) and the input/output terminal 120 (a first input/output terminal). The serial arm resonators 11 to 13 are formed as a plurality of serial arm resonant devices included in the acoustic wave filter 1.

One serial arm resonant device (acoustic wave resonant device) is composed of the serial arm resonator 11 only. The serial arm resonator 12 is an example of a second serial arm resonant device, and one serial arm resonant device (acoustic wave resonant device) is composed of the serial arm resonator 12 only. The serial arm resonator 13 is an example of a first serial arm resonant device, and one serial arm resonant device (acoustic wave resonant device) is composed of the serial arm resonator 13 only. The serial arm resonators 11 to 13 are connected in the order of the serial arm resonators 11, 12, and 13 from the input/output terminal 110.

The parallel arm resonator 21 is an example of an acoustic wave resonant device including an acoustic wave resonator and is connected between the serial arm path and the ground. One or more parallel arm resonant devices included in the acoustic wave filter 1 are composed of the one or more parallel arm resonators 21. The parallel arm resonator 21 is connected between the ground and a point of connection between the serial arm resonators 11 and 12. One parallel arm resonant device (acoustic wave resonant device) is composed of the parallel arm resonator 21 only.

The inductor 31 is an example of a first inductor and is connected between the ground and a first path connecting the serial arm resonators 12 and 13.

The serial arm resonator 13 is connected closest to the input/output terminal 120 among the serial arm resonators 11 to 13, the parallel arm resonator 21, and the inductor 31.

The serial arm resonator 13 also has the highest electrostatic capacitance among the serial arm resonators 11 to 13 and the parallel arm resonator 21 and has the highest resonant frequency among the serial arm resonators 11 to 13.

The acoustic wave filter 1 according to this embodiment is only required to include at least the serial arm resonators 12 and 13 as the plurality of serial arm resonant devices and may include four or more serial arm resonant devices including the serial arm resonators 12 and 13. The acoustic wave filter 1 according to this embodiment is only required to include at least the parallel arm resonator 21 as the one or more parallel arm resonant devices and may include two or more parallel arm resonant devices including the parallel arm resonator 21. In addition, in the acoustic wave filter 1 according to this embodiment, at least one of an inductor and a capacitor may be disposed in series on the serial arm path connecting the input/output terminal 110 and the serial arm resonator 12, and at least one of an inductor and a capacitor may be connected between the serial arm path and the ground. An inductor may be connected between the parallel arm resonator 21 and the ground.

Each of the serial arm resonators 11 to 13 and the parallel arm resonator 21 (acoustic wave resonant devices) has only one acoustic wave resonator but may be one of, for example, (1) a resonant device composed of a circuit including an acoustic wave resonator and at least one of a capacitor and an inductor connected in parallel to the acoustic wave resonator; (2) a resonant device composed of a circuit including an acoustic wave resonator and at least one of a capacitor and an inductor connected in series to the acoustic wave resonator; (3) a resonant device composed of a plurality of acoustic wave resonators connected in parallel; and (4) a resonant device composed of a plurality of acoustic wave resonators connected in series.

The acoustic wave filter 1 according to this embodiment may also include a longitudinally coupled resonant device in addition to the serial arm resonant devices and the parallel arm resonant device included in the ladder filter.

### 2 Structure of Acoustic Wave Resonator

The structure of the acoustic wave resonators (serial arm resonators and the parallel arm resonator) included in the acoustic wave filter 1 will then be exemplified.

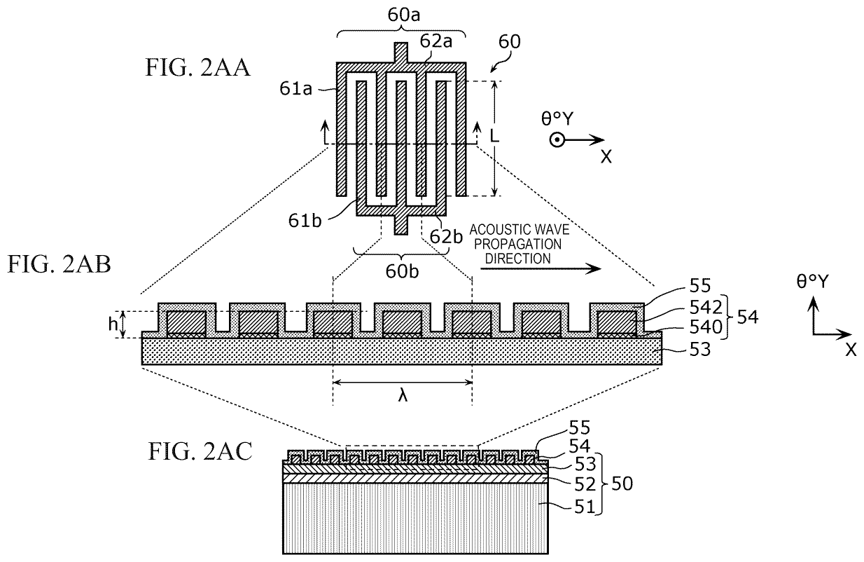

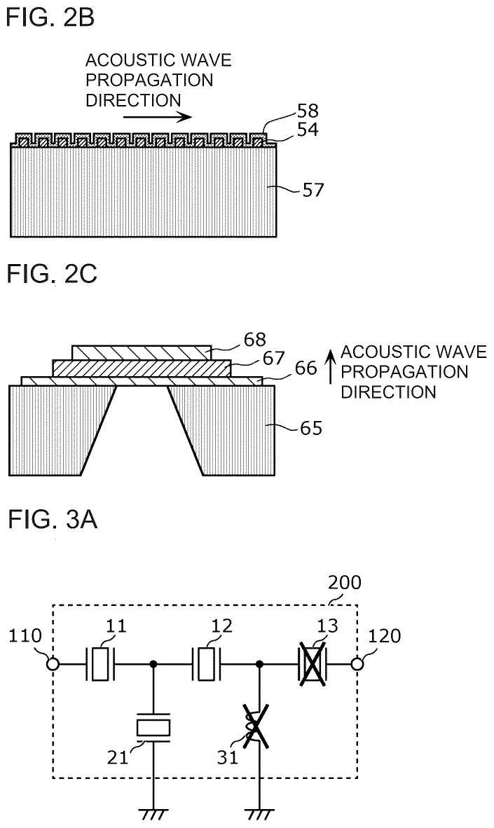

FIGS. 2AA-2AC depict a plan view and a cross-sectional view schematically illustrating a first example of the acoustic wave resonators included in the acoustic wave filter 1 according to the embodiment. FIGS. 2AA-2AC illustrate the basic structure of each of the plurality of acoustic wave resonators included in the acoustic wave filter 1. A surface acoustic wave resonator 60 illustrated in FIGS. 2AA-2AC is provided to explain a typical structure of the surface acoustic wave resonator included in the acoustic wave filter 1, and the number, the length, and the like of electrode fingers included in the electrode are not limited to these.

The surface acoustic wave resonator 60 includes a piezoelectric substrate 50 and comb-shaped electrodes 60a and 60b.

As illustrated in FIG. 2AA, a pair of comb-shaped electrodes 60a and 60b facing each other are formed on the piezoelectric substrate 50. The comb-shaped electrode 60a includes a plurality of electrode fingers 61a parallel to each other and a busbar electrode 62a connecting the plurality of electrode fingers 61a. The comb-shaped electrode 60b includes a plurality of electrode fingers 61b parallel to each other and a busbar electrode 62b connecting the plurality of electrode fingers 61b. The plurality of electrode fingers 61a and 61b are formed in a direction orthogonal to an acoustic wave propagation direction (X-axis direction).

An IDT electrode 54 including the plurality of electrode fingers 61a and 61b and the busbar electrodes 62a and 62b has a layered structure having a close-contact layer 540 and a main electrode layer 542, as illustrated in FIG. 2AB.

The close-contact layer 540 is a layer for improving close contact between the piezoelectric substrate 50 and the main electrode layer 542, and for example, Ti is used as a material thereof. As a material of the main electrode layer 542, for example, Al containing 1% Cu is used. A protection layer 55 is formed in such a manner as to cover the comb-shaped electrodes 60a and 60b. The protection layer 55 is a layer for protecting the main electrode layer 542 from an external environment, controlling a frequency temperature characteristic, increasing anti-humidity, and the like and is a dielectric film having, for example, silicon dioxide as a main component.

The materials of the close-contact layer 540, the main electrode layer 542, and the protection layer 55 are not limited to the materials described above. Further, the IDT electrode 54 does not have to have the layered structure above. The IDT electrode 54 may be formed from a metal, such as Ti, Al, Cu, Pt, Au, Ag, or Pd, or an alloy thereof and may also be composed of a plurality of multilayer bodies formed from the metal or the alloy above. The protection layer 55 does not have to be formed.

The layered structure of the piezoelectric substrate 50 will then be described.

As illustrated in FIG. 2AC, the piezoelectric substrate 50 includes a high-acoustic-velocity supporting substrate 51, a low-acoustic-velocity film 52, and a piezoelectric film 53 and has a structure in which the high-acoustic-velocity supporting substrate 51, the low-acoustic-velocity film 52, and the piezoelectric film 53 are stacked in this order.

The piezoelectric film 53 is formed from, for example, a θ° Y-cut X-propagating LiTaO₃ piezoelectric single crystal or a piezoelectric ceramic (a lithium tantalite single crystal or a ceramic that is cut along a plane with a normal line serving as an axis rotated by 8° from a Y axis with respect to an X axis serving as the center axis and in which a surface acoustic wave propagates in the X-axis direction). The material and the cut angle θ of the piezoelectric single crystal used as the piezoelectric film 53 are appropriately selected in accordance with the required specifications of the filters.

The high-acoustic-velocity supporting substrate 51 is a substrate that supports the low-acoustic-velocity film 52, the piezoelectric film 53, and the IDT electrode 54. Further, the high-acoustic-velocity supporting substrate 51 is a substrate in which the acoustic velocity of a bulk wave in the high-acoustic-velocity supporting substrate 51 is higher than that of an acoustic wave such as the surface acoustic wave propagating in the piezoelectric film 53 or a boundary acoustic wave. The high-acoustic-velocity supporting substrate 51 confines the surface acoustic wave in a portion where the piezoelectric film 53 and the low-acoustic-velocity film 52 are laminated and functions to prevent the surface acoustic wave from leaking to a portion lower than the high-acoustic-velocity supporting substrate 51. The high-acoustic-velocity supporting substrate 51 is, for example, a silicon substrate. As the material of the high-acoustic-velocity supporting substrate 51, for example, a piezoelectric body, such as aluminum nitride, lithium tantalate, lithium niobate, or crystal; ceramic, such as alumina, sapphire, magnesia, silicon nitride, silicon carbide, zirconia, cordierite, mullite, steatite, forsterite, spinel, or sialon; a dielectric, such as aluminum oxide, silicon oxynitride, diamond-like carbon (DLC), or diamond; a semiconductor such as silicon; or a material having any of the materials described above serving as a main component may be used. Spinel described above includes an aluminum compound containing one or more chemical elements selected from Mg, Fe, Zn, and Mn, and other elements and oxygen. As examples of spinel described above, MgAl₂O₄, FeAl₂O₄, ZnAl₂O₄, and MnAl₂O₄ may be cited.

The low-acoustic-velocity film 52 is a film in which the acoustic velocity of a bulk wave in the low-acoustic-velocity film 52 is lower than that of a bulk wave propagating in the piezoelectric film 53 and is disposed between the piezoelectric film 53 and the high-acoustic-velocity supporting substrate 51. This structure and the nature of concentration of the energy of the acoustic wave in a medium naturally having a low acoustic velocity prevent the surface acoustic wave energy from leaking to the outside of the piezoelectric film 53. As the material of the low-acoustic-velocity film 52, for example, a dielectric such as a compound obtained by adding fluorine, carbon, or boron to glass, silicon oxide, silicon oxynitride, lithium oxide, tantalic acid anhydride, or silicon oxide; or a material having any of the materials described above serving as a main component may be used.

The layered structure described above of the piezoelectric substrate 50 enables a Q value in the resonant frequency and the anti-resonant frequency to be made considerably higher than that in a structure in the related art in which a single layer piezoelectric substrate is used. That is, an acoustic wave resonator having a high Q value may be formed, and thus a filter having a low insertion loss may be formed by using the acoustic wave resonator.

The high-acoustic-velocity supporting substrate 51 may have a structure in which the supporting substrate and a high-acoustic-velocity film are laminated, the high-acoustic-velocity film having a higher acoustic velocity of the propagating bulk wave than the acoustic velocity of an acoustic wave such as a surface acoustic wave propagating in the piezoelectric film 53 or a boundary acoustic wave. In this case, as the material of the high-acoustic-velocity film, the same material as the material of the high-acoustic-velocity supporting substrate 51 may be used. As the material of the supporting substrate, for example, a piezoelectric body, such as aluminum nitride, lithium tantalate, lithium niobate, or crystal; ceramic, such as alumina, sapphire, magnesia, silicon nitride, silicon carbide, zirconia, cordierite, mullite, steatite, or forsterite; dielectric such as diamond or glass; a semiconductor, such as silicon or gallium nitride; a resin; or a material having any of the materials described above serving as a main component may be used.

In this specification, the phrase “the main component of a material” refers to a component in which the percentage of the component in the material exceeds 50% by weight. The main component described above may exist in one of single crystal, polycrystalline, and amorphous states or in a mixed state.

FIG. 2B is a cross-sectional view schematically illustrating a second example of the acoustic wave resonator included in the acoustic wave filter 1 according to the embodiment. For the surface acoustic wave resonator 60 illustrated in FIGS. 2AA-2AC, the example where the IDT electrode 54 is formed on the piezoelectric substrate 50 having the piezoelectric film 53 has been described; however, as illustrated in FIG. 2B, the substrate where the IDT electrode 54 is formed may be a single crystal piezoelectric substrate 57 composed of a single layer as a piezoelectric layer.

The single crystal piezoelectric substrate 57 is formed from, for example, a LiNbO₃ piezoelectric single crystal. The acoustic wave resonator according to this example includes the LiNbO₃ single crystal piezoelectric substrate 57, the IDT electrode 54, and a protection layer 58 formed on the single crystal piezoelectric substrate 57 and the IDT electrode 54.

The layered structure, the material, the cut angles, and the thickness of the piezoelectric film 53 and the single crystal piezoelectric substrate 57 that are described above may be appropriately changed depending on the required bandpass characteristics or the like of an acoustic wave filter device. Even an acoustic wave resonator using a LiTaO₃ piezoelectric substrate or the like having cut angles other than the cut angles described above may exert the same effects as those of the surface acoustic wave resonator 60 using the piezoelectric film 53 described above.

The substrate where the IDT electrode 54 is formed may have a structure in which a supporting substrate, an energy confinement layer, and a piezoelectric film are laminated in this order. The IDT electrode 54 is formed on the piezoelectric film. For the piezoelectric film, for example, a LiTaO₃ piezoelectric single crystal or a piezoelectric ceramic is used. The supporting substrate is a substrate that supports the piezoelectric film, the energy confinement layer, and the IDT electrode 54.

The energy confinement layer is composed of one or more layers, and the velocity of a bulk acoustic wave propagating in at least one of the layers is higher than the velocity of an acoustic wave propagating near the piezoelectric film. For example, the energy confinement layer may have a layered structure having a low-acoustic-velocity layer and a high-acoustic-velocity layer. The low-acoustic-velocity layer is a film in which the acoustic velocity of the acoustic wave propagating in the piezoelectric film is lower than the acoustic velocity of a bulk wave in the low-acoustic-velocity layer. The high-acoustic-velocity layer is a film in which the acoustic velocity of a bulk wave in the high-acoustic-velocity layer is higher than the acoustic velocity of the acoustic wave propagating in the piezoelectric film. The supporting substrate may be used as the high-acoustic-velocity layer.

The energy confinement layer may also be an acoustic impedance layer having a structure in which a low-acoustic-impedance layer having lower acoustic impedance and a high-acoustic-impedance layer having higher acoustic impedance are alternately stacked.

Electrode parameters of the IDT electrode 54 included in the surface acoustic wave resonator 60 is described.

The wavelength of an acoustic wave resonator is defined by the wavelength λ that is the repetition period of the electrode fingers 61a or 61b included in the IDT electrode 54 illustrated in FIG. 2AB. An electrode finger pitch is ½ of the wavelength λ. In a case where the line width of the electrode fingers 61a and 61b included in each of the comb-shaped electrodes 60a and 60b is W, and the width of a space between the electrode finger 61a and the electrode finger 61b adjacent to each other is S, the electrode finger pitch is defined as (W+S). The duty of the IDT electrode 54 is the line width share of each of the electrode fingers 61a and 61b, thus is a ratio of the line width of the electrode fingers 61a and 61b to a value obtained by adding the line width to the space width, and thus is defined as W/(W+S). The interdigital width of the IDT electrode 54 is a length of the electrode fingers overlapping when the electrode fingers 61a and the electrode fingers 61b are seen in the acoustic wave propagation direction (X-axis direction).

If a distance between adjacent electrode fingers is not fixed in the IDT electrode 54, the electrode finger pitch of the IDT electrode 54 is defined by the average electrode finger pitch of the IDT electrode 54. In a case where the total number of electrode fingers of the electrode fingers 61a and 61b included in the IDT electrode 54 is Ni, a distance between respective centers of the electrode finger located on one end, of the IDT electrode 54, in the acoustic wave propagation direction and the electrode finger located on the other end is Di, the average electrode finger pitch of the IDT electrode 54 is defined as Di/(Ni−1).

FIG. 2C is a cross-sectional view schematically illustrating a third example of the acoustic wave resonator included in the acoustic wave filter 1 according to the embodiment. FIG. 2C illustrates a bulk acoustic wave resonator as an acoustic wave resonator of the acoustic wave filter 1. As illustrated in FIG. 2C, the bulk acoustic wave resonator has, for example, a supporting substrate 65, a lower electrode 66, a piezoelectric layer 67, and an upper electrode 68 and has a configuration in which the supporting substrate 65, the lower electrode 66, the piezoelectric layer 67, and the upper electrode 68 are stacked in this order.

The supporting substrate 65 is a substrate for supporting the lower electrode 66, the piezoelectric layer 67, and the upper electrode 68 and is, for example, a silicon substrate. The supporting substrate 65 has a hollow portion in a part of area in contact with the lower electrode 66. This enables the piezoelectric layer 67 to vibrate freely.

The lower electrode 66 is an example of a first planar electrode and is formed on one of the surfaces of the supporting substrate 65. The upper electrode 68 is an example of a second planar electrode and is formed on the one surface of the supporting substrate 65. As the material of the lower electrode 66 and the upper electrode 68, for example, Al containing 1% Cu is used.

The piezoelectric layer 67 is an example of a piezoelectric thin film and is formed between the lower electrode 66 and the upper electrode 68. The piezoelectric layer 67 contains as a main component, at least one of, for example, zinc oxide (ZnO), aluminum nitride (AlN), lead zirconate titanate (PZT), potassium niobate (KN), lithium niobate (LN), lithium tantalate (LT), crystal, and lithium borate (LiBO).

The bulk acoustic wave resonator having the layered structure described above induces a bulk acoustic wave in the piezoelectric layer 67 by applying electrical energy between the lower electrode 66 and the upper electrode 68 and thus generates resonance. The bulk acoustic wave generated by this bulk acoustic wave resonator propagates in a portion between the lower electrode 66 and the upper electrode 68 in a direction perpendicular to the film surface of the piezoelectric layer 67. The bulk acoustic wave resonator is thus a resonator using the bulk acoustic wave.

### 3 Resonance Characteristics and Bandpass Characteristics of Acoustic Wave Filter 1

First, the basic operating principle of a ladder bandpass filter composed of one serial arm resonator and one parallel arm resonator is described.

The parallel arm resonator has a resonant frequency frp and an anti-resonant frequency fap (>frp), and the serial arm resonator has a resonant frequency frs and an anti-resonant frequency fas (>frs>frp). In the serial arm resonator and the parallel arm resonator having the resonance characteristic, the anti-resonant frequency fap of the parallel arm resonator and the resonant frequency frs of the serial arm resonator are typically made close to each other. This causes a frequency near the resonant frequency frp where the impedance of the parallel arm resonator is close to 0 to fall under a stopband on the low frequency side. If the frequency is increased further, the impedance of the parallel arm resonator is high near the anti-resonant frequency fap, and the impedance of the serial arm resonator is close to 0 near the resonant frequency frs. This causes a frequency near the anti-resonant frequency fap to the resonant frequency frs to fall under a signal pass band in a signal path serving as a serial arm path. A pass band on which the electrode parameter and the electromechanical coupling coefficient of the acoustic wave resonator are reflected may thereby be formed. Further, when the frequency is high and close to the anti-resonant frequency fas, the impedance of the serial arm resonator is high, and the frequency falls under a stopband on the high frequency side.

In each of the serial arm resonator and the parallel arm resonator, the impedance of the resonator represents capacitive impedance (capacitance) in a frequency band lower than the resonant frequency and inductive impedance (inductance) in a frequency band higher than the resonant frequency and lower than the anti-resonant frequency. The impedance of the resonator represents capacitive impedance in a frequency band higher than the anti-resonant frequency.

The impedance characteristics and bandpass characteristics of the acoustic wave filter 1 according to this embodiment and acoustic wave filters according to comparative examples will then be described.

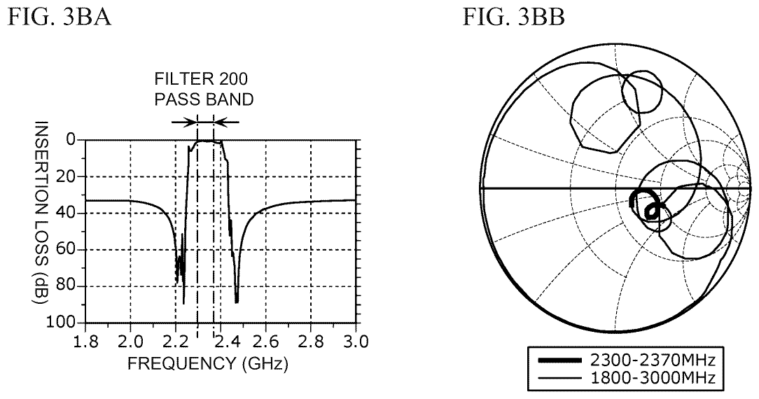

FIG. 3A is a view of the circuit configuration of an acoustic wave filter 200 according to Comparative Example 1. FIGS. 3BA and 3BB illustrate a Smith chart representing the bandpass characteristic and the impedance of the acoustic wave filter 200 according to Comparative Example 1. As illustrated in FIG. 3A, the acoustic wave filter 200 according to Comparative Example 1 has a configuration in which the serial arm resonator 13 and the inductor 31 are not disposed, as compared with the acoustic wave filter 1 according to the embodiment. The acoustic wave filter 200 according to Comparative Example 1 is thus a ladder acoustic wave filter including the serial arm resonators 11 and 12 and the parallel arm resonator 21.

In the following description, the acoustic wave filter 1 according to this embodiment and the acoustic wave filter according to Comparative Example have a pass band including, for example, Band B40A for LTE or Band n40A (2300 to 2370 MHz) for 5G-NR.

In the acoustic wave filter 200, the resonant frequencies of the serial arm resonators 11 and 12 and the anti-resonant frequency of the parallel arm resonator 21 are located in the pass band of the acoustic wave filter 200 based on basic operating principle of the ladder bandpass filter, and thereby the bandpass characteristic of the bandpass filter is obtained, as illustrated in FIG. 3BA. The impedance of the pass band is located on the capacitive and high impedance side. Accordingly, in a case where the low-noise amplifier 2 having the capacitive input impedance is connected to the input/output terminal 120, a matching element having inductive impedance and low transmission loss is required between the acoustic wave filter 200 and the low-noise amplifier 2.

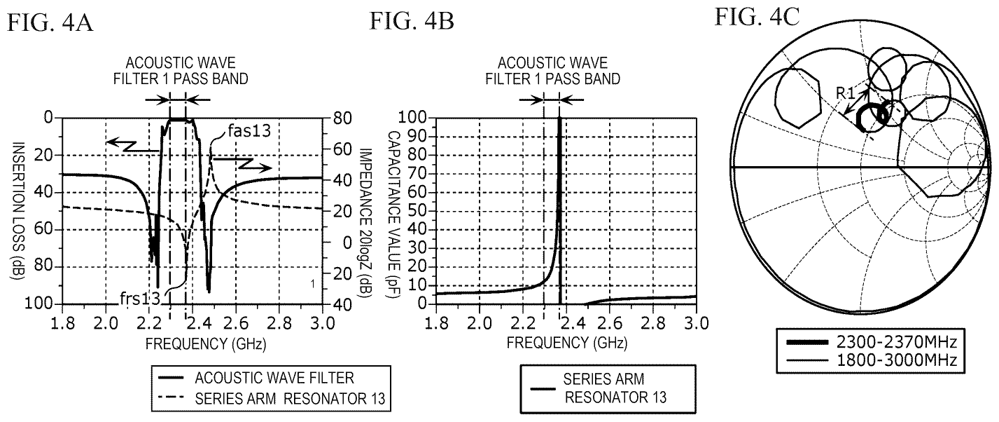

FIGS. 4A-4C illustrate a Smith chart representing the bandpass characteristic of the acoustic wave filter 1 according to the embodiment, the capacitance characteristic of the serial arm resonator 13, and the impedance of the acoustic wave filter 1. As compared with the acoustic wave filter 200 according to Comparative Example 1, the acoustic wave filter 1 according to the embodiment additionally has the serial arm resonator 13 and the inductor 31.

As illustrated in FIG. 4A, the serial arm resonator 13 has a resonant frequency frs13 leading to the minimum impedance and an anti-resonant frequency fas13 leading to the maximum impedance. The resonant frequency frs13 is located at the highest frequency end of the pass band of the acoustic wave filter 1. This causes the impedance of the serial arm resonator 13 in the pass band and the DC region of the acoustic wave filter 1 to be capacitive impedance. The capacitance value of the serial arm resonator 13 in the DC region is approximately 5 pF and is a sufficiently high capacitance value to block a DC component. Accordingly, even if a DC blocking capacitor is not disposed in series to a path connecting the acoustic wave filter 1 and the input port of the amplifying transistor of the low-noise amplifier 2, DC bias current to be supplied to the low-noise amplifier 2 may be prevented from leaking to the ground via the inductor 31.

In addition, as illustrated in FIG. 4B, the capacitance value of the serial arm resonator 13 at the highest frequency end of the pass band of the acoustic wave filter 1 increases in an exponential function manner and reaches 100 pF or higher, and the capacitance value of the serial arm resonator 13 at the lowest frequency end of the pass band also increases as compared with the capacitance value in the DC region and is approximately 13 pF. That is, the capacitance value of the serial arm resonator 13 in the pass band is an exceedingly high value as compared with the capacitance value in the DC region, impedance determined from the inverse of the capacitance value is low, and the serial arm resonator 13 is substantially in a short-circuited state.

Since the serial arm resonator 13 is substantially in the short-circuited state in the frequency band as the pass band described above, the inductor 31 thereby functions as the matching element having inductive impedance without necessarily being influenced by the serial arm resonator 13. Accordingly, if an external circuit is connected to the input/output terminal 120 having the capacitive impedance, matching loss in the pass band may be reduced, and the acoustic wave filter 1 in which the DC blocking in the DC region and the impedance matching in the pass band are ensured may be provided. In addition, DC bias current may be supplied to the low-noise amplifier 2 connected to the input/output terminal 120 with high accuracy, and matching loss of the radio frequency reception signal may be reduced. The radio frequency module 100 with reduced deterioration of the noise figure of the low-noise amplifier 2 may be provided.

The resonant frequency frs13 of the serial arm resonator 13 may be located at a frequency higher than or equal to the highest frequency end of the pass band. This enables the impedance of the serial arm resonator 13 in the pass band and the DC region to be capacitive impedance and enables the impedance in the pass band to be higher than the impedance in the DC region. The DC blocking and the impedance matching in the pass band may thus be ensured.

In addition, in this embodiment, the serial arm resonator 13 has the highest electrostatic capacitance among the serial arm resonators 11 to 13 and the parallel arm resonator 21.

This enables the capacitance value of the serial arm resonator 13 in the DC region to be the highest among the acoustic wave resonators included in the acoustic wave filter 1 and the impedance of the serial arm resonator 13 in the pass band to be exceedingly low. Accordingly, the matching loss in the pass band may be reduced considerably, and the acoustic wave filter 1 in which the DC blocking in the DC region and the impedance matching in the pass band are ensured may be provided.

The serial arm resonator 13 does not have to have the resonant frequency frs13 located at the frequency higher than or equal to the highest frequency end of the pass band and may have the highest resonant frequency among the serial arm resonators 11 to 13. This enables the impedance of the serial arm resonator 13 in the DC region to be capacitive impedance, the impedance of the serial arm resonator 13 in the pass band to be substantially capacitive impedance, and the impedance in the pass band to be higher than the impedance in the DC region. The DC blocking and the impedance matching in the pass band may thus be ensured. Further, since the resonant frequency frs13 of the serial arm resonator 13 is located in a higher frequency region of the pass band, insertion loss in the higher frequency region may be reduced, and what is called a drop of the bandpass characteristic in the highest frequency end in the pass band described above may be prevented.

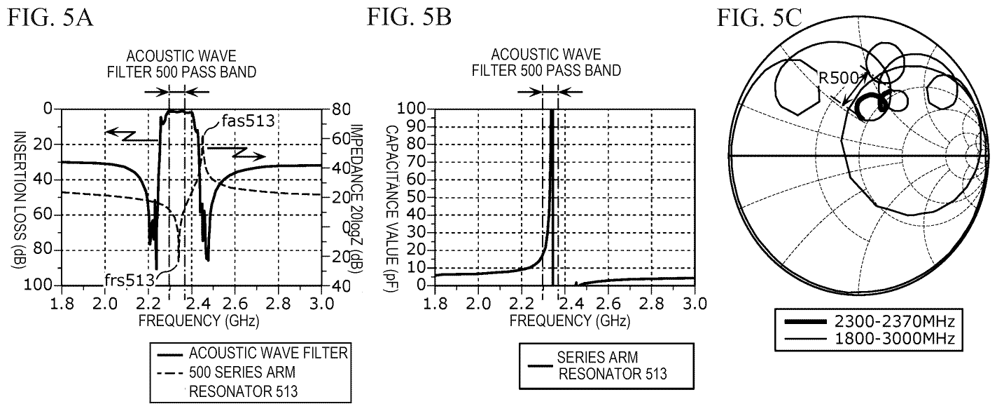

FIGS. 5A-5C illustrate a Smith chart representing the bandpass characteristic of an acoustic wave filter 500 according to Comparative Example 2, the capacitance characteristic of a serial arm resonator 513, and the impedance of the acoustic wave filter 500. The acoustic wave filter 500 according to Comparative Example 2 includes the serial arm resonators 11, 12, and 513, the parallel arm resonator 21, the inductor 31, and the input/output terminals 110 and 120. The acoustic wave filter 500 according to Comparative Example 2 is different from the acoustic wave filter 1 according to the embodiment only in that the serial arm resonator 13 is replaced with the serial arm resonator 513. Hereinafter, the acoustic wave filter 500 according to Comparative Example 2 will be described in such a manner that the description of the same configuration as that of the acoustic wave filter 1 according to the embodiment is omitted and focus is placed on a different configuration.

The serial arm resonators 11, 12, and 513 are connected in the order of the serial arm resonators 11, 12, and 513 from the input/output terminal 110. The serial arm resonator 513 is connected closest to the input/output terminal 120 among the serial arm resonators 11, 12, and 513, the parallel arm resonator 21, and the inductor 31.

The serial arm resonator 513 has the highest electrostatic capacitance among the serial arm resonators 11, 12, and 513 and the parallel arm resonator 21. In addition, as illustrated in FIG. 5A, a resonant frequency frs513 of the serial arm resonator 513 is located near the center of the pass band of the acoustic wave filter 500.

The serial arm resonator 513 has the highest electrostatic capacitance among the serial arm resonators 11, 12, and 513 and the parallel arm resonator 21. In addition, as illustrated in FIG. 5A, the impedance of the serial arm resonator 513 in the DC region is capacitive impedance. The capacitance value of the serial arm resonator 513 in the DC region is approximately 5 pF and is a sufficiently high capacitance value to block the DC component. Accordingly, DC bias current to be supplied to the low-noise amplifier 2 may be prevented from leaking to the ground via the inductor 31.

In contrast, as illustrated in FIGS. 5A and 5B, the serial arm resonator 513 has capacitive impedance at lower frequencies in the pass band and has a high capacitance value; however, the serial arm resonator 513 has inductive impedance at higher frequencies in the pass band and has a low capacitance value. This causes the serial arm resonator 513 to be in the short-circuited state at the lower frequencies in the pass band but not to be in the short-circuited state at the higher frequencies in the pass band. The inductor 31 is thereby influenced by the serial arm resonator 13 at the higher frequencies in the pass band, and thus the degree of the impedance matching is lowered.

Further, as illustrated in FIG. 5C, in the acoustic wave filter 500 according to Comparative Example 2, the serial arm resonator 513 has capacitive impedance at lower frequencies in the pass band, and a constant resistance circle is shifted counterclockwise. The serial arm resonator 513 has inductive impedance at higher frequencies in the pass band, and the constant resistance circle is shifted clockwise. This causes the spread (R500 in FIG. 5C) of the impedance trajectory in the pass band of the acoustic wave filter 500 to be larger than the spread (R1 in FIG. 4C) of the impedance trajectory in the pass band of the acoustic wave filter 1. That is, the degree of impedance concentration in the pass band of the acoustic wave filter 500 is lowered as compared with the degree of impedance concentration in the pass band of the acoustic wave filter 1. Accordingly, signal transmission loss in the pass band of the acoustic wave filter 500 is increased.

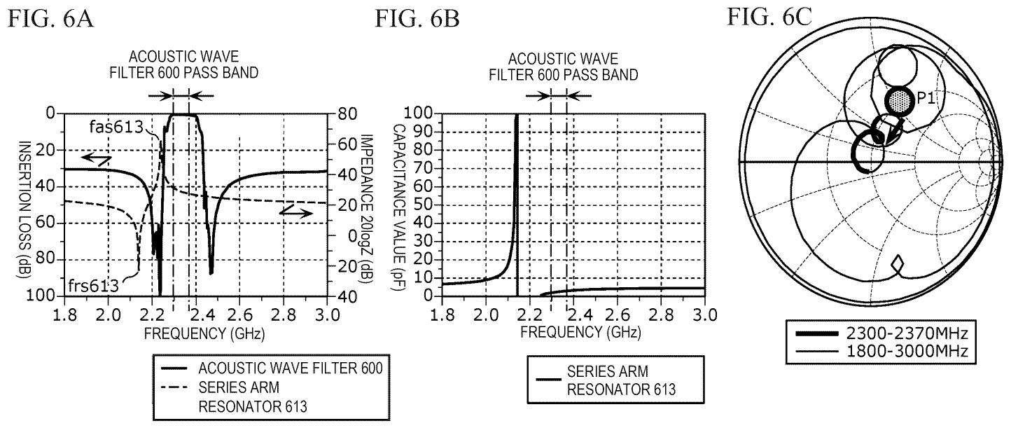

FIGS. 6A-6C illustrates a Smith chart representing the bandpass characteristic of an acoustic wave filter 600 according to Comparative Example 3, the capacitance characteristic of a serial arm resonator 613, and the impedance of the acoustic wave filter 600. The acoustic wave filter 600 according to Comparative Example 3 includes the serial arm resonators 11, 12, and 613, the parallel arm resonator 21, the inductor 31, and the input/output terminals 110 and 120. The acoustic wave filter 600 according to Comparative Example 3 is different from the acoustic wave filter 1 according to the embodiment only in that the serial arm resonator 13 is replaced with the serial arm resonator 613. Hereinafter, the acoustic wave filter 600 according to Comparative Example 3 will be described in such a manner that the description of the same configuration as that of the acoustic wave filter 1 according to the embodiment is omitted and focus is placed on a different configuration.

The serial arm resonators 11, 12, and 613 are connected in the order of the serial arm resonators 11, 12, and 613 from the input/output terminal 110. The serial arm resonator 613 is connected closest to the input/output terminal 120 among the serial arm resonators 11, 12, and 613, the parallel arm resonator 21, and the inductor 31.

The serial arm resonator 613 has the highest electrostatic capacitance among the serial arm resonators 11, 12, and 613 and the parallel arm resonator 21. In addition, as illustrated in FIG. 6A, a resonant frequency frs613 and an anti-resonant frequency fas613 of the serial arm resonator 613 are located at frequencies lower than the lowest frequency end of the pass band of the acoustic wave filter 600.

The serial arm resonator 613 has the highest electrostatic capacitance among the serial arm resonators 11, 12, and 613 and the parallel arm resonator 21. In addition, as illustrated in FIG. 6A, the impedance of the serial arm resonator 613 in the DC region is capacitive impedance. The capacitance value of the serial arm resonator 613 in the DC region is higher than or equal to 5 pF and is a sufficiently high capacitance value to block the DC component. Accordingly, DC bias current to be supplied to the low-noise amplifier 2 may be prevented from leaking to the ground via the inductor 31.

In contrast, as illustrated in FIGS. 6A and 6B, the impedance of the serial arm resonator 613 in the pass band of the acoustic wave filter 600 is capacitive impedance but has a low capacitance value. Accordingly, the impedance of the serial arm resonator 613 in the pass band is high. As illustrated in FIG. 6C, even if the inductor 31 causes the impedance of the acoustic wave filter 600 in the pass band to move to an inductive region P1, the serial arm resonator 613 having the high capacitive impedance causes the impedance of the acoustic wave filter 600 in the pass band to move largely counterclockwise in the constant resistance circle and thus leads to low inductive reactance. Impedance matching with the low-noise amplifier 2 connected to the input/output terminal 120 is thereby insufficient, and the matching loss of the radio frequency reception signal is increased.

### 4 Terminal Layout of Acoustic Wave Filter 1

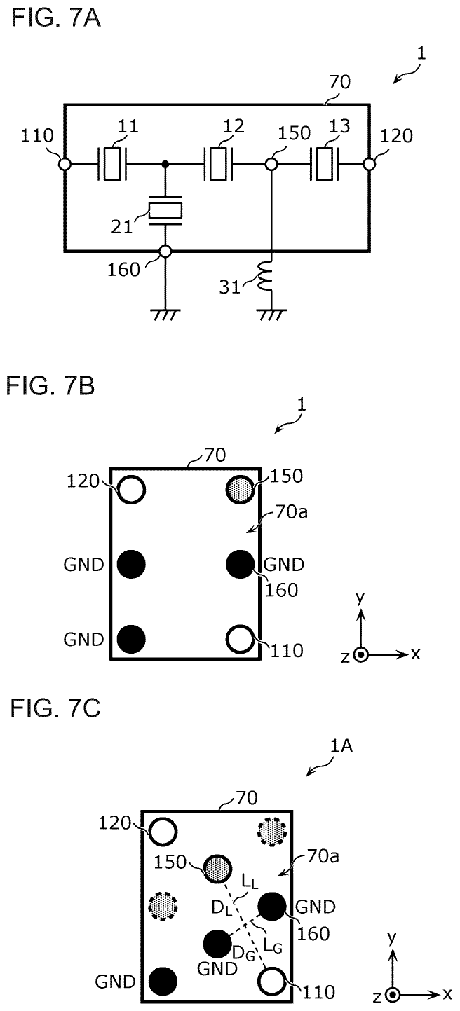

The terminal layout of the acoustic wave filter 1 according to this embodiment will then be described. FIG. 7A is a view of the circuit configuration of the acoustic wave filter 1 according to the embodiment. FIG. 7B is a plan view of the electrode layout of the acoustic wave filter 1 according to the embodiment.

As illustrated in FIG. 7A, the acoustic wave filter 1 includes a substrate 70 in addition to the circuit configuration of the acoustic wave filter 1 illustrated in FIG. 1. The serial arm resonators 11 to 13, the parallel arm resonator 21, the input/output terminals 110 and 120, a terminal 150, and a ground terminal 160 are disposed on the substrate 70. This enables the acoustic wave filter 1 to be downsized.

The terminal 150 is an example of a first terminal, is a node on a path connecting the serial arm resonators 12 and 13, and is connected to the inductor 31. The ground terminal 160 is connected to the parallel arm resonator 21 and is set at the ground potential.

The substrate 70 is an example of a first substrate and has main surfaces 70a and 70b facing each other. If each of the serial arm resonators 11 to 13 and the parallel arm resonator 21 is the surface acoustic wave resonator including the IDT electrode 54, the substrate 70 has piezoelectricity and corresponds to the piezoelectric substrate 50 illustrated in FIGS. 2AA-2AC or the single crystal piezoelectric substrate 57 illustrated in FIG. 2B. If each of the serial arm resonators 11 to 13 and the parallel arm resonator 21 is a bulk acoustic wave resonator including a multilayer body having the lower electrode 66, the piezoelectric layer 67, and the upper electrode 68 in this order from the main surface 70a or 70b, the substrate 70 includes silicon and corresponds to the supporting substrate 65 illustrated in FIG. 2C.

As illustrated in FIG. 7B, the input/output terminals 110 and 120, the terminal 150, and the ground terminal 160 are disposed on the main surface 70a. The IDT electrode and the multilayer body described above may be disposed on any of the main surfaces 70a and 70b. In plan view of the main surface 70a, the ground terminal 160 is disposed between the terminal 150 and the input/output terminal 110.

Since the ground terminal 160 is disposed between the terminal 150 and the input/output terminal 110, deterioration of the attenuation band of the acoustic wave filter 1 due to the electromagnetic coupling (electrical field coupling or magnetic coupling) between the inductor 31 connected to the terminal 150 and the input/output terminal 110 may thereby be prevented.

The ground terminal disposed between the terminal 150 and the input/output terminal 110 does not have to be the ground terminal 160 and may be a different ground terminal (GND).

FIG. 7C is a plan view of the electrode layout of an acoustic wave filter 1A according to Modification 1 of the embodiment. The acoustic wave filter 1A according to Modification 1 has the same circuit configuration as that of the acoustic wave filter 1 according to the embodiment and is different only in the terminal configuration. Accordingly, the terminal configuration of the acoustic wave filter 1A according to Modification 1 will hereinafter be described.

As illustrated in FIG. 7C, a plurality of ground terminals (GNDs) are disposed on the main surface 70a. In plan view of the main surface 70a, a virtual line LL (first virtual line) connecting the terminal 150 and the input/output terminal 110 crosses a virtual line LG (second virtual line) connecting two of the plurality of ground terminals (GNDs), and a length DG of the virtual line LG is shorter than a length DL of the virtual line LL.

Since the electromagnetic shielding region composed of the plurality of ground terminals (GNDs) is formed between the terminal 150 and the input/output terminal 110, deterioration of the attenuation band of the acoustic wave filter 1A due to electromagnetic coupling between the inductor 31 connected to the terminal 150 and the input/output terminal 110 may thereby be prevented.

The ground terminal disposed to cross the virtual line connecting the terminal 150 and the input/output terminal 110 does not have to include the ground terminal 160 and may be a different ground terminal (GND).

### 5 Component Layout of Radio Frequency Module 100A

The circuit configuration and the component configuration of a radio frequency module 100A according to Modification 2 of this embodiment will then be described.

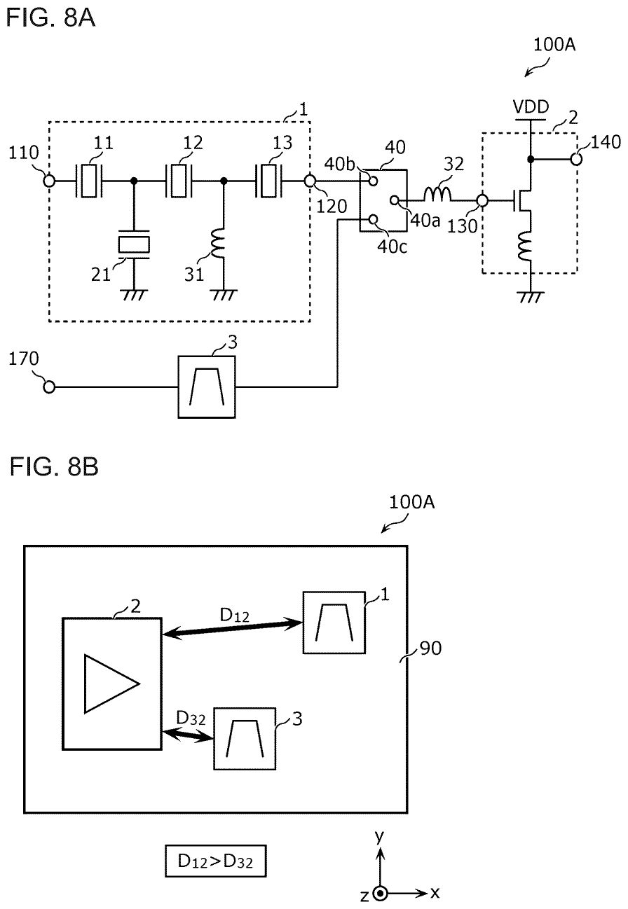

FIG. 8A is a view of the circuit configuration of the radio frequency module 100A according to Modification 2 of the embodiment. FIG. 8B is a plan view of the component configuration of the radio frequency module 100A according to Modification 2 of the embodiment.

As illustrated in FIG. 8A, the radio frequency module 100A according to this modification includes the acoustic wave filter 1, the low-noise amplifier 2, a filter 3, a switch 40, and the inductor 32.

The acoustic wave filter 1 is the acoustic wave filter 1 according to the embodiment and is connected to the input terminal 130 of the low-noise amplifier 2 with the switch 40 and the inductor 32 interposed therebetween. The filter 3 is an example of a first filter and has one end connected to the input terminal 130 with the switch 40 and the inductor 32 interposed therebetween and the other end connected to an input/output terminal 170.

The switch 40 has a common terminal 40a, a selection terminal 40b (first selection terminal), and a selection terminal 40c (second selection terminal) and performs switching between connection between the common terminal 40a and the selection terminal 40b and connection between the common terminal 40a and the selection terminal 40c. The common terminal 40a is connected to the input terminal 130 with the inductor 32 interposed therebetween, the selection terminal 40b is connected to the input/output terminal 120, and the selection terminal 40c is connected to the filter 3.

The configuration above enables the radio frequency module 100A to select one of a reception signal having passed through the acoustic wave filter 1 and a reception signal having passed through the filter 3 and to amplify the reception signal at the low-noise amplifier 2.

In the radio frequency module 100A, at least one of the switch 40 and the inductor 32 does not have to be provided.

As illustrated in FIG. 8B, the radio frequency module 100A further includes a mounting substrate 90. On the mounting substrate 90, the acoustic wave filter 1, the filter 3, and the low-noise amplifier 2 are disposed. The switch 40 and the inductor 32 may be disposed on the mounting substrate 90.

As the mounting substrate 90, for example, one of a low temperature co-fired ceramics (LTCC) substrate and a high temperature co-fired ceramics (HTCC) substrate that have a layered structure of a plurality of dielectric layers, a substrate having components built therein, a substrate having a redistribution layer (RDL), a printing circuit board, or the like may be used, but the mounting substrate 90 is not limited to these.

A distance D12 between the low-noise amplifier 2 and the acoustic wave filter 1 is longer than a distance D32 between the low-noise amplifier 2 and the filter 3.

Even if the wiring element connecting the acoustic wave filter 1 and the low-noise amplifier 2 is long, the inductor 31 included in the acoustic wave filter 1 may thereby override the influence of parasitic capacitance occurring on the wiring element. The filter 3 desirably having a short wiring element for connection to the low-noise amplifier 2 may thereby be disposed between the acoustic wave filter 1 and the low-noise amplifier 2, and thus the radio frequency module 100A that is downsized and has reduced signal transmission loss may be provided.

### 6 Effects and the Like

As described above, the acoustic wave filter 1 according to this embodiment includes the plurality of serial arm resonant devices including the serial arm resonators 12 and 13 disposed on the serial arm path connecting the input/output terminals 110 and 120, the one or more parallel arm resonant devices including the parallel arm resonator 21 connected between the serial arm path and the ground, and the inductor 31 connected between the ground and the first path connecting the serial arm resonators 12 and 13. The serial arm resonator 13 is connected closest to the input/output terminal 120 among the plurality of serial arm resonant devices, the one or more parallel arm resonant devices, and the inductor 31, and the serial arm resonator 13 has the highest resonant frequency among the plurality of serial arm resonant devices.

Since the serial arm resonator 13 has the highest the resonant frequency, the impedance of the serial arm resonator 13 in the pass band the DC region of the acoustic wave filter 1 is thereby capacitive impedance. Accordingly, even if a DC blocking capacitor is not disposed in series to the path connecting the input/output terminal 120 and the external circuit, a DC component may be prevented from leaking to the ground via the inductor 31. In addition, the capacitance value of the serial arm resonator 13 in the pass band is an exceedingly high value as compared with the capacitance value in the DC region, the impedance of the serial arm resonator 13 in the pass band is low, and the serial arm resonator 13 is substantially in the short-circuited state. The inductor 31 thereby functions as the matching element having inductive impedance in the frequency band as the pass band without necessarily being influenced by the serial arm resonator 13. Accordingly, if the external circuit is connected to the input/output terminal 120 having the capacitive impedance, the matching loss in the pass band may be reduced, and the acoustic wave filter 1 in which the DC blocking and the impedance matching in the pass band are ensured may be provided. In addition, in the radio frequency module 100 having the low-noise amplifier 2 serving as the external circuit connected to the input/output terminal 120, DC bias current may be supplied to the low-noise amplifier 2 with high accuracy, and the matching loss of the radio frequency reception signal may be reduced. Accordingly, the noise figure of the low-noise amplifier 2 may be prevented from being deteriorated.

For example, in the acoustic wave filter 1, the serial arm resonator 13 has the highest electrostatic capacitance among the plurality of serial arm resonant devices and the one or more parallel arm resonant devices.

This enables the capacitance value of the serial arm resonator 13 in the DC region to be the highest among the acoustic wave resonators included in the acoustic wave filter 1 and the impedance of the serial arm resonator 13 in the pass band to be exceedingly low. Accordingly, the matching loss in the pass band may be reduced considerably, and the acoustic wave filter 1 in which the DC blocking in the DC region and the impedance matching in the pass band are ensured may be provided.

For example, in the acoustic wave filter 1, the resonant frequency frs13 of the serial arm resonator 13 is located at a frequency higher than or equal to the highest frequency end of the pass band of the acoustic wave filter 1.

This causes the entire pass band of in the acoustic wave filter 1, the impedance of the serial arm resonator 13 to be capacitive impedance, and the matching loss in the pass band may be reduced considerably if the external circuit having capacitive impedance is connected to the input/output terminal 120.

For example, the acoustic wave filter 1 further includes the substrate 70 having the main surfaces 70a and 70b facing each other. Each acoustic wave resonator included in a corresponding one of the serial arm resonators 11 to 13 and the parallel arm resonator 21 is formed on the substrate 70, and the input/output terminals 110 and 120, the terminal 150 on the first path connected to the inductor 31, and the ground terminal 160 are disposed on the main surface 70a.

This causes the acoustic wave resonators included in the acoustic wave filter 1 to be integrated on the substrate 70, and thus the acoustic wave filter 1 may be downsized.

For example, in the acoustic wave filter 1, in plan view of the main surface 70a, the ground terminal 160 is disposed between the terminal 150 and the input/output terminal 110.

Deterioration of the attenuation band of the acoustic wave filter 1 due to electromagnetic coupling between the inductor 31 connected to the terminal 150 and the input/output terminal 110 may thereby be prevented.

For example, in the acoustic wave filter 1A according to Modification 1, the plurality of ground terminals are disposed on the main surface 70a. In addition, in plan view of the main surface 70a, the virtual line LL connecting the terminal 150 and the input/output terminal 110 crosses the virtual line LG connecting two of the plurality of ground terminals, and the virtual line LG is shorter than the virtual line LL.

Since the electromagnetic shielding region composed of the plurality of ground terminals is formed between the terminal 150 and the input/output terminal 110, deterioration of the attenuation band of the acoustic wave filter 1A due to electromagnetic coupling between the inductor 31 connected to the terminal 150 and the input/output terminal 110 may thereby be prevented.

For example, in the acoustic wave filter 1 (1A), the substrate 70 has piezoelectricity, and each acoustic wave resonator included in a corresponding one of the serial arm resonators 11 to 13 and the parallel arm resonator 21 includes the IDT electrode.

The acoustic wave filter 1 (1A) is thereby the ladder filter composed of the surface acoustic wave resonators.

For example, in the acoustic wave filter 1 (1A), the substrate 70 includes silicon, each acoustic wave resonator included in a corresponding one of the serial arm resonators 11 to 13 and the parallel arm resonator 21 includes the multilayer body having the lower electrode 66, the piezoelectric layer 67, and the upper electrode 68 in this order from the main surface 70a or 70b.

The acoustic wave filter 1 (1A) is thereby the ladder filter composed of the bulk acoustic wave resonator.

The radio frequency module 100 according to this embodiment includes the acoustic wave filter 1 and the low-noise amplifier 2 having the input terminal 130 connected to the input/output terminal 120.

The serial arm resonator 13 thereby has the DC blocking function and is in the short-circuited state in the pass band. Accordingly, DC bias current may be supplied to the low-noise amplifier 2 with high accuracy, and the matching loss of the radio frequency reception signal in the pass band may be reduced. The noise figure of the low-noise amplifier 2 may thus be prevented from being deteriorated.

For example, in the radio frequency module 100, the capacitor is not disposed in series to the path connecting the input/output terminal 120 and the input terminal of the amplifying transistor included in the low-noise amplifier 2.

This enables the deterioration of the noise figure of the low-noise amplifier due to the occurrence of impedance mismatching in the pass band caused by the capacitor.

For example, the radio frequency module 100A according to Modification 2 further includes the filter 3 connected to the input terminal 130, the acoustic wave filter 1, and the mounting substrate 90 on which the filter 3 and the low-noise amplifier 2 are disposed, and the distance between the low-noise amplifier 2 and the acoustic wave filter 1 is longer than the distance between the low-noise amplifier 2 and the filter 3.

Even if the wiring element connecting the acoustic wave filter 1 and the low-noise amplifier 2 is long, the inductor 31 included in the acoustic wave filter 1 may thereby override the influence of parasitic capacitance occurring on the wiring element. The filter 3 desirably having a short wiring element for connection to the low-noise amplifier 2 may thereby be disposed between the acoustic wave filter 1 and the low-noise amplifier 2, and thus the radio frequency module 100A that is downsized and has reduced signal transmission loss may be provided.

For example, the radio frequency module 100A further includes the switch 40 that has the common terminal 40a and the selection terminals 40b and 40c and performs switching between the connection between the common terminal 40a and the selection terminal 40b and the connection between the common terminal 40a and the selection terminal 40c. The common terminal 40a is connected to the input terminal 130, the selection terminal 40b is connected to the input/output terminal 120, and the selection terminal 40c is connected to the filter 3.

This enables the radio frequency module 100A to select one of the reception signal having passed through the acoustic wave filter 1 and the reception signal having passed through the filter 3 and to amplify the reception signal at the low-noise amplifier 2.

### Other Embodiments

The acoustic wave filter and the radio frequency module according to the present disclosure have heretofore been described by using the embodiment and the modifications; however, the present disclosure is not limited to the embodiment and the modifications that are described above. A modification obtained by applying, to the embodiment and the modifications above, a modification conceived of those skilled in the art without necessarily departing from the spirit of the present disclosure, and various types of equipment having the acoustic wave filter and the radio frequency module according to the present disclosure built therein are also included in the present disclosure.

For example, in the acoustic wave filter and the radio frequency module according to the above-mentioned embodiment and the modifications, a matching element such as an inductor or a capacitor and a switching circuit may be connected between the components.

The features of the acoustic wave filter and the radio frequency module described based on the above-mentioned embodiment and the modifications will hereinafter be described.

<1>

An acoustic wave filter includes:
a plurality of serial arm resonant devices including a first serial arm resonant device and a second serial arm resonant device, the first serial arm resonant device being disposed on a serial arm path connecting a first input/output terminal and a second input/output terminal;
one or more parallel arm resonant devices connected between the serial arm path and ground; and
a first inductor connected between the ground and a first path connecting the first serial arm resonant device and the second serial arm resonant device.

The first serial arm resonant device is connected closest to the first input/output terminal among the plurality of serial arm resonant devices, the one or more parallel arm resonant devices, and the first inductor, and
the first serial arm resonant device has a highest electrostatic capacitance among the plurality of serial arm resonant devices and the one or more parallel arm resonant devices and has a highest resonant frequency among the plurality of serial arm resonant devices.

<2>

In the acoustic wave filter according to Claim 1,
the first serial arm resonant device has highest electrostatic capacitance among the plurality of serial arm resonant devices and the one or more parallel arm resonant devices.

<3>

In the acoustic wave filter according to <1> or <2>,
a resonant frequency of the first serial arm resonant device is located at a frequency higher than or equal to a highest frequency end of a pass band of the acoustic wave filter.

<4>

The acoustic wave filter according to any one of <1> to <3> further includes:
a first substrate having a first main surface and a second main surface facing each other.

An acoustic wave resonator included in each of the plurality of serial arm resonant devices and each of the one or more parallel arm resonant devices is formed on the first substrate, and
the first input/output terminal, the second input/output terminal, a first terminal, and a ground terminal are disposed on the first main surface, the first terminal being connected to the first inductor and being on the first path.

<5>

In the acoustic wave filter according to <4>,
in plan view of the first main surface, the ground terminal is disposed between the first terminal and the second input/output terminal.

<6>

In the acoustic wave filter according to <4>,
a plurality of the ground terminals are disposed on the first main surface.

In plan view of the first main surface, a first virtual line connecting the first terminal and the second input/output terminal crosses a second virtual line connecting two ground terminals of the plurality of ground terminals, and
the second virtual line is shorter than the first virtual line.

<7>

In the acoustic wave filter according to any one of <4> to <6>,
the first substrate has piezoelectricity, and
the acoustic wave resonator included in each of the plurality of serial arm resonant devices and each of the one or more parallel arm resonant devices includes an IDT electrode.

<8>

In the acoustic wave filter according to any one of <4> to <6>,
the first substrate includes silicon, and
the acoustic wave resonator included in each of the plurality of serial arm resonant devices and each of the one or more parallel arm resonant devices includes a multilayer body having a first planar electrode, a piezoelectric thin film, and a second planar electrode in this order from the first main surface or the second main surface.

<9>

A radio frequency module includes:
the acoustic wave filter according to any one of <1> to <8>; and
a low-noise amplifier having an input terminal connected to the first input/output terminal.

<10>

In the radio frequency module according to <9>, a capacitor is not disposed in series to a path connecting the first input/output terminal and an input port of an amplifying transistor included in the low-noise amplifier.

<11>

The radio frequency module according to <9> or <10> further includes:
a first filter connected to the input terminal; and
a mounting substrate on which the acoustic wave filter, the first filter, and the low-noise amplifier are disposed.

A distance between the low-noise amplifier and the acoustic wave filter is longer than a distance between the low-noise amplifier and the first filter.

<12>

The radio frequency module according to <11> further includes:
a switch that has a common terminal, a first selection terminal, and a second selection terminal and that performs switching between connection between the common terminal and the first selection terminal and connection between the common terminal and the second selection terminal.

The common terminal is connected to the input terminal,
the first selection terminal is connected to the first input/output terminal, and
the second selection terminal is connected to the first filter.

The present disclosure may be widely used for communications equipment such as a mobile phone, as an acoustic wave filter and a radio frequency module with low loss that are applicable to a frequency standard for multiband.

What is claimed is:

1. An acoustic wave filter comprising:
a plurality of serial arm resonant devices including a first serial arm resonant device and a second serial arm resonant device, the first serial arm resonant device being disposed on a serial arm path connecting a first input/output terminal and a second input/output terminal;
one or more parallel arm resonant devices connected between the serial arm path and ground; and
a first inductor connected between ground and a first path connecting the first serial arm resonant device and the second serial arm resonant device,
wherein the first serial arm resonant device is connected closest to the first input/output terminal among the plurality of serial arm resonant devices, the one or more parallel arm resonant devices, and the first inductor, and
wherein the first serial arm resonant device has a highest resonant frequency among the plurality of serial arm resonant devices.

2. The acoustic wave filter according to claim 1,
wherein the first serial arm resonant device has a highest electrostatic capacitance among the plurality of serial arm resonant devices and the one or more parallel arm resonant devices.

3. The acoustic wave filter according to claim 1,
wherein a resonant frequency of the first serial arm resonant device is located at a frequency higher than or equal to a highest frequency end of a pass band of the acoustic wave filter.

4. The acoustic wave filter according to claim 1, further comprising:
a first substrate having a first main surface and a second main surface facing each other,
wherein an acoustic wave resonator included in each of the plurality of serial arm resonant devices and each of the one or more parallel arm resonant devices is formed on the first substrate, and
wherein the first input/output terminal, the second input/output terminal, a first terminal, and a ground terminal are disposed on the first main surface, the first terminal being connected to the first inductor and being disposed on the first path.

5. The acoustic wave filter according to claim 4,
wherein in plan view of the first main surface, the ground terminal is disposed between the first terminal and the second input/output terminal.

6. The acoustic wave filter according to claim 4,
wherein the ground terminal is one of a plurality of ground terminals disposed on the first main surface,
wherein in plan view of the first main surface, a first virtual line connecting the first terminal and the second input/output terminal crosses a second virtual line connecting two ground terminals of the plurality of ground terminals, and
wherein the second virtual line is shorter than the first virtual line.

7. The acoustic wave filter according to claim 4,
wherein the first substrate has piezoelectricity, and
wherein the acoustic wave resonator included in each of the plurality of serial arm resonant devices and each of the one or more parallel arm resonant devices comprises an interdigital transducer electrode.

8. The acoustic wave filter according to claim 4,
wherein the first substrate comprises silicon, and
wherein the acoustic wave resonator included in each of the plurality of serial arm resonant devices and each of the one or more parallel arm resonant devices comprises a multilayer body having a first planar electrode, a piezoelectric thin film, and a second planar electrode in this order from the first main surface or the second main surface.

9. A radio frequency module comprising:
the acoustic wave filter according to claim 1; and
a low-noise amplifier having an input terminal connected to the first input/output terminal.

10. The radio frequency module according to claim 9,
wherein a capacitor is not disposed in series on a path connecting the first input/output terminal and an input port of an amplifying transistor included in the low-noise amplifier.

11. The radio frequency module according to claim 9, further comprising:
a first filter connected to the input terminal; and
a mounting substrate on which the acoustic wave filter, the first filter, and the low-noise amplifier are disposed,
wherein a distance between the low-noise amplifier and the acoustic wave filter is longer than a distance between the low-noise amplifier and the first filter.

12. The radio frequency module according to claim 11, further comprising:
a switch that has a common terminal, a first selection terminal, and a second selection terminal and that performs switching between a connection between the common terminal and the first selection terminal and a connection between the common terminal and the second selection terminal,
wherein the common terminal is connected to the input terminal,
wherein the first selection terminal is connected to the first input/output terminal, and
wherein the second selection terminal is connected to the first filter.

13. The acoustic wave filter according to claim 2,
wherein a resonant frequency of the first serial arm resonant device is located at a frequency higher than or equal to the highest frequency end of a pass band of the acoustic wave filter.

14. The acoustic wave filter according to claim 2, further comprising:
a first substrate having a first main surface and a second main surface facing each other,
wherein an acoustic wave resonator included in each of the plurality of serial arm resonant devices and each of the one or more parallel arm resonant devices is formed on the first substrate, and
wherein the first input/output terminal, the second input/output terminal, a first terminal, and a ground terminal are disposed on the first main surface, the first terminal being connected to the first inductor and being disposed on the first path.

15. The acoustic wave filter according to claim 14,
wherein in plan view of the first main surface, the ground terminal is disposed between the first terminal and the second input/output terminal.

16. The acoustic wave filter according to claim 14,
wherein a plurality of ground terminals is disposed on the first main surface, the plurality of ground terminals including said ground terminal,
wherein in plan view of the first main surface, a first virtual line connecting the first terminal and the second input/output terminal crosses a second virtual line connecting two ground terminals of the plurality of ground terminals, and
wherein the second virtual line is shorter than the first virtual line.

17. The acoustic wave filter according to claim 14,
wherein the first substrate has piezoelectricity, and
wherein the acoustic wave resonator included in each of the plurality of serial arm resonant devices and each of the one or more parallel arm resonant devices comprises an interdigital transducer electrode.

18. The acoustic wave filter according to claim 14,
wherein the first substrate comprises silicon, and
wherein the acoustic wave resonator included in each of the plurality of serial arm resonant devices and each of the one or more parallel arm resonant devices comprises a multilayer body having a first planar electrode, a piezoelectric thin film, and a second planar electrode in this order from the first main surface or the second main surface.

19. A radio frequency module comprising:
the acoustic wave filter according to claim 2; and
a low-noise amplifier having an input terminal connected to the first input/output terminal.

20. The radio frequency module according to claim 19,
wherein a capacitor is not disposed in series on a path connecting the first input/output terminal and an input port of an amplifying transistor included in the low-noise amplifier.
